(19) United States
(12) Patent Application Publication
(10) Pub. No.: US 2023/0016894 A1
(43) Pub. Date: Jan. 19, 2023

(54) UNDERCUT ELECTRODES FOR A GAS DISCHARGE LASER CHAMBER

(71) Applicant: Cymer, LLC, San Diego, CA (US)

(72) Inventors: Edward Siqi Luo, San Diego, CA (US); Zhou Wang, San Diego, CA (US)

(21) Appl. No.: 17/789,362

(22) PCT Filed: Dec. 10, 2020
(86) PCT No.: PCT/US2020/064373

§ 371 Date: Jun. 27, 2022

Related U.S. Application Data
(60) Provisional application No. 62/955,542, filed on Dec. 31, 2019.
(60) Provisional application No. 63/029,099, filed on May 22, 2020.

(51) Int. Cl. H01S 3/038; H01S 3/036; H01S 3/225; G03F 7/20; H01S 3/134; H01S 3/034

(52) U.S. Cl. CPC H01S 3/0385; H01S 3/036; H01S 3/225; H01S 3/0381; H01S 3/0382; G03F 7/70025; G03F 7/70033; H01S 3/0388; H01S 3/134; H01S 3/0346

(57) ABSTRACT

Provided is a light source apparatus and an electrode design for use in a discharge chamber of the light source apparatus. The discharge chamber is configured to hold a gas discharge medium configured to output a light beam. The light source apparatus include a pair of opposed electrodes configured to excite a gas medium to form a discharge plasma. At least one electrode of the pair of opposing electrodes may include recessed portions or hollowed-out portions at each end of the electrode, or at other suitable locations. The disclosed electrode structures improve uniformity of the erosion profile of the electrodes, significantly extending the lifespan of the discharge chamber by redistributing the discharge particle flux through the electrode with an optimized design of the electrode geometry, as the local discharge particle flux is reduced at the recessed portions.

### CROSS REFERENCE TO RELATED APPLICATIONS

This application claims priority to U.S. Application No. 62/955,542, filed Dec. 31, 2019, titled UNDERCUT ELECTRODES FOR A LIGHT SOURCE; and U.S. Application No. 63/029,099, filed May 22, 2020, titled UNDERCUT ELECTRODES FOR A GAS DISCHARGE LASER CHAMBER, both of which are incorporated herein in their entireties by reference.

### FIELD

The present disclosure relates to laser systems such as excimer lasers that produce light and, more particularly, to an optimized electrode design for discharge plasma in a gas discharge laser.

### BACKGROUND

A lithographic apparatus is a machine constructed to apply a desired pattern onto a substrate. A lithographic apparatus can be used, for example, in the manufacture of integrated circuits (ICs). A lithographic apparatus may, for example, project a pattern of a patterning device (e.g., a mask, a reticle) onto a layer of radiation-sensitive material (photoresist or, simply, “resist”) provided on a substrate.

To project a pattern on a substrate a lithographic apparatus may use electromagnetic radiation. The wavelength of this radiation determines the minimum size of features which can be formed on the substrate. A lithographic apparatus, which uses deep ultraviolet (DUV) radiation, having a wavelength within the range 20-400 nm, for example 193 nm or 248 nm, may be used to form features on a substrate.

A master oscillator power amplifier (MOPA) or a master oscillator power ring amplifier (MOPRA) is a two-stage laser system that produces a highly coherent amplified light beam. The performance of the MOPA or the MOPRA can depend critically on the master oscillator (MO), the power amplifier (PA), and/or the power ring amplifier (PRA). Electrodes of the MO, the PA, and/or the PRA surround a gas medium that is energized into a discharge plasma. The electrodes can be eroded over time due to the corrosive nature of the gas and plasma. The discharge intensity may not be uniform along the length of the electrodes. Often, the discharge intensity is highest at the end of the electrodes, and it can also be higher at the center compared to the rest of the length. The relatively elevated local discharge intensity at the ends or middle of the discharge may cause increased erosion of the corresponding locations on the electrode. As the discharge plasma is generated by the breakdown of gas between the electrodes, the uneven erosion of the electrodes can result in poor discharge quality of the plasma and therefore require the premature replacement of the discharge chamber.

### SUMMARY

Accordingly, there is a need to control the erosion uniformity of the electrodes, which thereby increases the lifetime of the electrodes.

In some embodiments, a light source apparatus includes a chamber configured to hold a gas medium. The discharge chamber may be configured to output a light beam. The light source apparatus may also include a pair of opposed electrodes configured to excite the gas into plasma (through the so-called break down process). In some embodiments, at least one electrode of the pair of opposing electrodes includes recessed portions formed at each end of the at least one electrode.

In some embodiments, each electrode of the pair of electrodes includes a first surface that inwardly faces the gas medium and, after excitation, the plasma, and a second surface opposite the first surface, and the recessed portions of the at least one electrode are formed within the second surface at each end of the second surface or on the second surface interior from the ends.

In some embodiments, the at least one electrode includes a bulk thickness and a planar first surface inwardly facing the plasma, and the recessed portions include an undercut portion wherein the ends of the at least one electrode have a thickness less than the bulk thickness.

In some embodiments, the at least one electrode of the pair of electrodes includes an anode.

In some embodiments, the at least one electrode of the pair of electrodes comprises a cathode.

In some embodiments, each electrode of the pair of electrodes comprises recessed portions formed at each end.

In some embodiments, each electrode of the pair of electrodes includes a first surface inwardly facing the gas medium and, after excitation, the discharge plasma and a second surface opposite the first surface, and the recessed portions of the at least one electrode are formed between the first and second surfaces.

Note that, hereinafter, the gas medium and the discharge plasma formed from the gas medium, may be referred collectively as the gas discharge medium, for brevity of description.

In some embodiments, the gas discharge medium comprises halogen gasses and noble gasses to form an excimer and/or an exciplex.

In some embodiments, the light source further includes a set of optical elements configured to form an optical resonator around the chamber.

In some embodiments, an undercut electrode includes a first surface inwardly facing the gas discharge medium, a second surface opposite the first surface, and locally recessed or undercut portions formed by undercutting into the second surface, or between the first and second surfaces, i.e. “hollowed-out”.

In some embodiments, the undercut electrode includes a bulk thickness and a planar first surface inwardly facing the gas discharge medium, and the recessed portions comprises an undercut portion within the second surface wherein the ends of the undercut electrode have a thickness less than the bulk thickness.

In some embodiments, the recessed portions are formed between the first and second surfaces.

In some embodiments, the recessed portions comprise rectangular shaped recesses.

In some embodiments, the recessed portions comprise curved recesses.

In some embodiments, the undercut electrode comprises an anode.

In some embodiments, the undercut electrode comprises a cathode.

In some embodiments, a pair of opposing electrodes are configured to break down a gas into plasma. Each electrode of the pair of electrodes includes a first surface inwardly facing the plasma and a second surface opposite the first surface. In some embodiments, at least one electrode of the pair of opposing electrodes includes recessed portions formed at each end of the at least one electrode.

In some embodiments, the at least one electrode includes a bulk thickness and the first surface comprises a planar surface inwardly facing the gas discharge medium, and wherein the recessed portions comprises an undercut portion wherein the ends of the at least one electrode have a thickness less than the bulk thickness.

In some embodiments, the recessed portions comprise rectangular shaped recesses.

In some embodiments, the recessed portions comprise curved recesses.

In some embodiments, each electrode of the pair of electrodes comprises recessed portions formed at each end.

In some embodiments, a light source apparatus includes a chamber configured to hold a gas discharge medium and a pair of opposed electrodes configured to excite the gas discharge medium to produce a plasma that produces an output light beam. In some embodiments, the at least one electrode of the pair of opposing electrodes includes at least one of a recessed portion or a hollowed-out portion.

In some embodiments, each electrode of the pair of electrodes includes a first surface inwardly facing the gas discharge medium and a second surface opposite the first surface. The at least one electrode may include the recessed portion, with the recessed portion being formed within the second surface.

In some embodiments, the recessed portion may be located along a centerline of the at least one electrode.

In some embodiments, the recessed portion may be located at an end of the at least one electrode.

In some embodiments, the recessed portion may be offset from a centerline of the at least one electrode.

In some embodiments, the recessed portion includes a plurality of recessed portions.

In some embodiments, the plurality of recessed portions may be located at each end of the at least one electrode.

In some embodiments, each electrode of the pair of electrodes includes a first surface inwardly facing the gas discharge medium and a second surface opposite the first surface. In some embodiments, the at least one electrode includes the hollowed-out portion, with the hollowed-out portion being formed between the first and second surfaces.

In some embodiments, the hollowed-out portion is located along a centerline of the at least one electrode.

In some embodiments, the hollowed-out portion is offset from a centerline of the at least one electrode.

In some embodiments, the hollowed-out portion includes a plurality of hollowed-out portions.

In some embodiments, the least one electrode may include both a recessed portion and a hollowed-out portion.

In some embodiments, the at least one of the recessed portion or the hollowed-out portion may be filled with a non-conductive material.

Implementations of any of the techniques described above may include a DUV light source, a system, a method, a process, a device, and/or an apparatus. The details of one or more implementations are set forth in the accompanying drawings and the description below. Other features will be apparent from the description and drawings, and from the claims.

Further features and exemplary aspects of the embodiments, as well as the structure and operation of various embodiments, are described in detail below with reference to the accompanying drawings. It is noted that the embodiments are not limited to the specific embodiments described herein. Such embodiments are presented herein for illustrative purposes only. Additional embodiments will be apparent to persons skilled in the relevant art(s) based on the teachings contained herein.

### BRIEF DESCRIPTION OF THE DRAWINGS

The accompanying drawings, which are incorporated herein and form part of the specification, illustrate the embodiments and, together with the description, further serve to explain the principles of the embodiments and to enable a person skilled in the relevant art(s) to make and use the embodiments.

FIG. 1A is a schematic illustration of a reflective lithographic apparatus, according to an exemplary embodiment.

FIG. 1B is a schematic illustration of a transmissive lithographic apparatus, according to an exemplary embodiment.

FIG. 2 is a schematic illustration of a light source apparatus, according to an exemplary embodiment.

FIGS. 3-13 illustrate example undercut electrodes, according to exemplary embodiments.

FIG. 14 illustrates a graph demonstrating erosion rates of electrodes, according to an exemplary embodiment.

The features and exemplary aspects of the embodiments will become more apparent from the Detailed Description set forth below when taken in conjunction with the drawings, in which like reference characters identify corresponding elements throughout. In the drawings, like reference numbers generally indicate identical, functionally similar, and/or structurally similar elements. Additionally, generally, the left-most digit(s) of a reference number identifies the drawing in which the reference number first appears. Unless otherwise indicated, the drawings provided throughout the disclosure should not be interpreted as to-scale drawings.

### DETAILED DESCRIPTION

This specification discloses one or more embodiments that incorporate the features of this present invention. The disclosed embodiment(s) merely exemplify the present invention. The scope of the invention is not limited to the disclosed embodiment(s). The present invention is defined by the claims appended hereto.

The embodiment(s) described, and references in the specification to “one embodiment,” “an embodiment,” “an example embodiment,” “an exemplary embodiment,” etc., indicate that the embodiment(s) described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is understood that it is within the knowledge of one skilled in the art to effect such feature, structure, or characteristic in connection with other embodiments whether or not explicitly described.

Spatially relative terms, such as “beneath,” “below,” “lower,” “above,” “on,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The term “about” or “substantially” or “approximately” as used herein indicates the value of a given quantity that can vary based on a particular technology. Based on the particular technology, the term “about” or “substantially” or “approximately” can indicate a value of a given quantity that varies within, for example, 1-15% of the value (e.g., ±1%, ±2%, ±5%, ±10%, or ±15% of the value).

Embodiments of the disclosure may be implemented in hardware, firmware, software, or any combination thereof. Embodiments of the disclosure may also be implemented as instructions stored on a machine-readable medium, which may be read and executed by one or more processors. A machine-readable medium may include any mechanism for storing or transmitting information in a form readable by a machine (e.g., a computing device). For example, a machine-readable medium may include read only memory (ROM); random access memory (RAM); magnetic disk storage media; optical storage media; flash memory devices; electrical, optical, acoustical or other forms of propagated signals (e.g., carrier waves, infrared signals, digital signals, etc.), and others. Further, firmware, software, routines, and/or instructions may be described herein as performing certain actions. However, it should be appreciated that such descriptions are merely for convenience and that such actions in fact result from computing devices, processors, controllers, or other devices executing the firmware, software, routines, instructions, etc.

Before describing such embodiments in more detail, however, it is instructive to present an example environment in which embodiments of the present disclosure may be implemented.

Exemplary Lithographic System

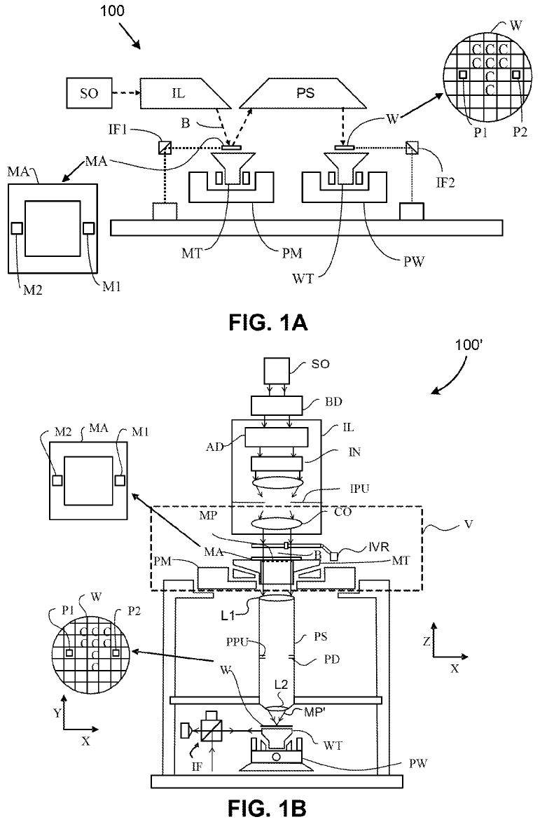

FIGS. 1A and 1B are schematic illustrations of a lithographic apparatus 100 and lithographic apparatus 100′, respectively, in which embodiments of the present invention may be implemented. Lithographic apparatus 100 and lithographic apparatus 100′ each include the following: an illumination system (illuminator) IL configured to condition a radiation beam B (for example, deep ultraviolet (DUV) radiation); a support structure (for example, a mask table) MT configured to support a patterning device (for example, a mask, a reticle, or a dynamic patterning device) MA and connected to a first positioner PM configured to accurately position the patterning device MA; and, a substrate table (for example, a wafer table) WT configured to hold a substrate (for example, a photoresist coated wafer) W and connected to a second positioner PW configured to accurately position the substrate W. Lithographic apparatus 100 and 100′ also have a projection system PS configured to project a pattern imparted to the radiation beam B by patterning device MA onto a target portion (for example, comprising one or more dies) C of the substrate W. In lithographic apparatus 100, the patterning device MA and the projection system PS are reflective. In lithographic apparatus 100′, the patterning device MA and the projection system PS are transmissive.

The illumination system IL may include various types of optical components, such as refractive, reflective, catadioptric, magnetic, electromagnetic, electrostatic, or other types of optical components, or any combination thereof, for directing, shaping, or controlling the radiation beam B.

The support structure MT holds the patterning device MA in a manner that depends on the orientation of the patterning device MA with respect to a reference frame, the design of at least one of the lithographic apparatus 100 and 100′, and other conditions, such as whether or not the patterning device MA is held in a vacuum environment. The support structure MT may use mechanical, vacuum, electrostatic, or other clamping techniques to hold the patterning device MA. The support structure MT can be a frame or a table, for example, which can be fixed or movable, as required. By using sensors, the support structure MT can ensure that the patterning device MA is at a desired position, for example, with respect to the projection system PS.

The term “patterning device” MA should be broadly interpreted as referring to any device that can be used to impart a radiation beam B with a pattern in its cross-section, such as to create a pattern in the target portion C of the substrate W. The pattern imparted to the radiation beam B can correspond to a particular functional layer in a device being created in the target portion C to form an integrated circuit.

The patterning device MA may be transmissive (as in lithographic apparatus 100′ of FIG. 1B) or reflective (as in lithographic apparatus 100 of FIG. 1A). Examples of patterning devices MA include reticles, masks, programmable mirror arrays, or programmable LCD panels. Masks are well known in lithography, and include mask types such as binary, alternating phase shift, or attenuated phase shift, as well as various hybrid mask types. An example of a programmable mirror array employs a matrix arrangement of small mirrors, each of which can be individually tilted so as to reflect an incoming radiation beam in different directions. The tilted mirrors impart a pattern in the radiation beam B which is reflected by a matrix of small mirrors.

The term “projection system” PS can encompass any type of projection system, including refractive, reflective, catadioptric, magnetic, electromagnetic and electrostatic optical systems, or any combination thereof, as appropriate for the exposure radiation being used, or for other factors, such as the use of an immersion liquid on the substrate W or the use of a vacuum. A vacuum environment can be used for DUV or electron beam radiation since other gases can absorb too much radiation or electrons. A vacuum environment can therefore be provided to the whole beam path with the aid of a vacuum wall and vacuum pumps.

Lithographic apparatus 100 and/or lithographic apparatus 100′ can be of a type having two (dual stage) or more substrate tables WT (and/or two or more mask tables). In such “multiple stage” machines, the additional substrate tables WT can be used in parallel, or preparatory steps can be carried out on one or more tables while one or more other substrate tables WT are being used for exposure. In some situations, the additional table may not be a substrate table WT.

The lithographic apparatus may also be of a type wherein at least a portion of the substrate may be covered by a liquid having a relatively high refractive index, e.g., water, so as to fill a space between the projection system and the substrate. An immersion liquid may also be applied to other spaces in the lithographic apparatus, for example, between the mask and the projection system Immersion techniques are well known in the art for increasing the numerical aperture of projection systems. The term “immersion” as used herein does not mean that a structure, such as a substrate, must be submerged in liquid, but rather only means that liquid is located between the projection system and the substrate during exposure.

Referring to FIGS. 1A and 1B, the illuminator IL receives a radiation beam from a radiation source SO. The source SO and the lithographic apparatus 100, 100′ can be separate physical entities, for example, when the source SO is an excimer laser (e.g., master oscillator power amplifier (MOPA) or master oscillator power ring amplifier (MOPRA)). In such cases, the source SO is not considered to form part of the lithographic apparatus 100 or 100′, and the radiation beam B passes from the source SO to the illuminator IL with the aid of a beam delivery system BD (in FIG. 1B) including, for example, suitable directing mirrors and/or a beam expander. In other cases, the source SO can be an integral part of the lithographic apparatus 100, 100′, for example, when the source SO is a mercury lamp. The source SO and the illuminator IL, together with the beam delivery system BD, if required, can be referred to as a radiation system.

The illuminator IL can include an adjuster AD (in FIG. 1B) for adjusting the angular intensity distribution of the radiation beam. Generally, at least the outer and/or inner radial extent (commonly referred to as “σ-outer” and “σ-inner,” respectively) of the intensity distribution in a pupil plane of the illuminator can be adjusted. In addition, the illuminator IL can comprise various other components (in FIG. 1B), such as an integrator IN and a condenser CO. The illuminator IL can be used to condition the radiation beam B to have a desired uniformity and intensity distribution in its cross section.

Referring to FIG. 1A, the radiation beam B is incident on the patterning device (for example, mask) MA, which is held on the support structure (for example, mask table) MT, and is patterned by the patterning device MA. In lithographic apparatus 100, the radiation beam B is reflected from the patterning device (for example, mask) MA. After being reflected from the patterning device (for example, mask) MA, the radiation beam B passes through the projection system PS, which focuses the radiation beam B onto a target portion C of the substrate W. With the aid of the second positioner PW and position sensor IF2 (for example, an interferometric device, linear encoder, or capacitive sensor), the substrate table WT can be moved accurately (for example, so as to position different target portions C in the path of the radiation beam B). Similarly, the first positioner PM and another position sensor IF1 can be used to accurately position the patterning device (for example, mask) MA with respect to the path of the radiation beam B. Patterning device (for example, mask) MA and substrate W can be aligned using mask alignment marks M1, M2 and substrate alignment marks P1, P2.

Referring to FIG. 1B, the radiation beam B is incident on the patterning device (for example, mask MA), which is held on the support structure (for example, mask table MT), and is patterned by the patterning device. Having traversed the mask MA, the radiation beam B passes through the projection system PS, which focuses the beam onto a target portion C of the substrate W. The projection system has a pupil conjugate PPU to an illumination system pupil IPU. Portions of radiation emanate from the intensity distribution at the illumination system pupil IPU and traverse a mask pattern without being affected by diffraction at the mask pattern and create an image of the intensity distribution at the illumination system pupil IPU.

The projection system PS projects an image MV of the mask pattern MP, where image MV is formed by diffracted beams produced from the mark pattern MP by radiation from the intensity distribution, onto a photoresist layer coated on the substrate W. For example, the mask pattern MP may include an array of lines and spaces. A diffraction of radiation at the array and different from zeroth order diffraction generates diverted diffracted beams with a change of direction in a direction perpendicular to the lines. Undiffracted beams (i.e., so-called zeroth order diffracted beams) traverse the pattern without any change in propagation direction. The zeroth order diffracted beams traverse an upper lens or upper lens group of the projection system PS, upstream of the pupil conjugate PPU of the projection system PS, to reach the pupil conjugate PPU. The portion of the intensity distribution in the plane of the pupil conjugate PPU and associated with the zeroth order diffracted beams is an image of the intensity distribution in the illumination system pupil IPU of the illumination system IL. The aperture device PD, for example, is disposed at or substantially at a plane that includes the pupil conjugate PPU of the projection system PS.

The projection system PS is arranged to capture, by means of an upper lens or upper lens group L1 and a lower lens or lower lens group L2, not only the zeroth order diffracted beams, but also first-order or first- and higher-order diffracted beams (not shown). In some embodiments, dipole illumination for imaging line patterns extending in a direction perpendicular to a line may be used to utilize the resolution enhancement effect of dipole illumination. For example, first-order diffracted beams interfere with corresponding zeroth-order diffracted beams at the level of the wafer W to create an image MV of the line pattern MP at highest possible resolution and process window (i.e., usable depth of focus in combination with tolerable exposure dose deviations). In some embodiments, astigmatism aberration may be reduced by providing radiation poles (not shown) in opposite quadrants of the illumination system pupil IPU. For example, the illumination at the illumination system pupil IPU may use only two opposite illumination quadrants, sometimes referred to as BMW illumination, such that the remaining two quadrants are not used in the illumination but are configured to capture first-order diffracted beams. Further, in some embodiments, astigmatism aberration may be reduced by blocking the zeroth order beams in the pupil conjugate PPU of the projection system associated with radiation poles in opposite quadrants.

With the aid of the second positioner PW and position sensor IF (for example, an interferometric device, linear encoder, or capacitive sensor), the substrate table WT can be moved accurately (for example, so as to position different target portions C in the path of the radiation beam B). Similarly, the first positioner PM and another position sensor (not shown in FIG. 1B) can be used to accurately position the mask MA with respect to the path of the radiation beam B (for example, after mechanical retrieval from a mask library or during a scan).

In general, movement of the mask table MT can be realized with the aid of a long-stroke module (coarse positioning) and a short-stroke module (fine positioning), which form part of the first positioner PM. Similarly, movement of the substrate table WT can be realized using a long-stroke module and a short-stroke module, which form part of the second positioner PW. In the case of a stepper (as opposed to a scanner), the mask table MT can be connected to a short-stroke actuator only or can be fixed. Mask MA and substrate W can be aligned using mask alignment marks M1, M2, and substrate alignment marks P1, P2. Although the substrate alignment marks (as illustrated) occupy dedicated target portions, they can be located in spaces between target portions (known as scribe-lane alignment marks). Similarly, in situations in which more than one die is provided on the mask MA, the mask alignment marks can be located between the dies.

Mask table MT and patterning device MA can be in a vacuum chamber V, where an in-vacuum robot IVR can be used to move patterning devices such as a mask in and out of vacuum chamber. Alternatively, when mask table MT and patterning device MA are outside of the vacuum chamber, an out-of-vacuum robot can be used for various transportation operations, similar to the in-vacuum robot IVR. Both the in-vacuum and out-of-vacuum robots need to be calibrated for a smooth transfer of any payload (e.g., mask) to a fixed kinematic mount of a transfer station.

The lithographic apparatus 100 and 100′ can be used in at least one of the following modes:

1. In step mode, the support structure (for example, mask table) MT and the substrate table WT are kept essentially stationary, while an entire pattern imparted to the radiation beam B is projected onto a target portion C at one time (i.e., a single static exposure). The substrate table WT is then shifted in the X and/or Y direction so that a different target portion C can be exposed.

2. In scan mode, the support structure (for example, mask table) MT and the substrate table WT are scanned synchronously while a pattern imparted to the radiation beam B is projected onto a target portion C (i.e., a single dynamic exposure). The velocity and direction of the substrate table WT relative to the support structure (for example, mask table) MT can be determined by the (de-)magnification and image reversal characteristics of the projection system PS.

3. In another mode, the support structure (for example, mask table) MT is kept substantially stationary holding a programmable patterning device, and the substrate table WT is moved or scanned while a pattern imparted to the radiation beam B is projected onto a target portion C. A pulsed radiation source SO can be employed and the programmable patterning device is updated as required after each movement of the substrate table WT or in between successive radiation pulses during a scan. This mode of operation can be readily applied to maskless lithography that utilizes a programmable patterning device, such as a programmable mirror array.

Combinations and/or variations on the described modes of use or entirely different modes of use can also be employed.

In a further embodiment, lithographic apparatus 100 includes an extreme ultraviolet (EUV) source, which is configured to generate a beam of EUV radiation for EUV lithography.

A relative vacuum, i.e. a small amount of gas (e.g. hydrogen) at a pressure well below atmospheric pressure, may be provided in the radiation source SO, in the illumination system IL, and/or in the projection system PS. The radiation source SO may be a laser produced plasma (LPP) source, a discharge produced plasma (DPP) source, a free electron laser (FEL), an excimer laser, a master oscillator power amplifier (MOPA), a master oscillator power ring amplifier (MOPRA), or any other radiation source that is capable of generating DUV radiation.

### Exemplary Light Source Apparatus

The uneven erosion of an electrode for discharge plasma in a gas discharge laser limits the lifespan of the discharge chamber. The uneven erosion can be significantly improved by redistributing the discharge intensity throughout the electrode with an optimized design of the electrode geometry. The undercut and/or hollowed-out electrode disclosed here reduces the local discharge intensity at the location of the undercut or hollowed-out section of the electrode, therefore evening out the erosion profile, and increasing the lifespan of the discharge chamber. In some embodiments, the undercut electrode disclosed here reduces the local plasma discharge intensity at both ends of the electrodes to even out the erosion profile and increase the lifespan of the discharge chamber.

As discussed above, a master oscillator power amplifier (MOPA) or a master oscillator power ring amplifier (MOPRA) is a two-stage laser system. The master oscillator (MO) (e.g., first optical resonator stage) produces a highly coherent light beam. The power amplifier (PA) or the power ring amplifier (PRA) (e.g., second optical resonator stage) amplifies the beam power while preserving the beam properties. The MO can include a gas discharge chamber, an optical coupler (OC), and a linewidth narrowing module (LNM). The OC and the LNM surround the gas discharge chamber to form an optical resonator. The PA or the PRA can include a second gas discharge chamber, a wavefront engineering box (WEB), and a beam reverser (BR). The WEB and the BR can surround the second gas discharge chamber to form a second optical resonator. For example, certain MOPAs and MOPRAs have been previously described in U.S. Pat. No. 7,643,528, issued Jan. 5, 2010, and U.S. Pat. No. 7,822,092, issued Oct. 26, 2010, which are hereby incorporated by reference herein in their entireties.

As an example of MOPA/MOPRA system or MO-only system, an excimer laser utilizes an excimer (e.g., excited dimer) or an exciplex (e.g., excited complex) to output deep ultraviolet (DUV) radiation. An excimer is a short-lived homodimeric molecule formed from two species (e.g., Ar₂, Kr₂, F₂, Xe₂). An exciplex is a heterodimeric molecule formed from more than two species (e.g., ArF, KrCl, KrF, XeBr, XeCl, XeF). Electrodes of the MO, the PA, and/or the PRA surrounding the plasma generated by breaking down the gas (e.g., F₂, ArF, KrF, and/or XeF) can become eroded over time and produce metal fluoride dust (e.g., average diameter of about 2.0 μm). Metal fluoride dust can undesirably settle on the optical windows of the MO, the PA, and/or the PRA and can lead to optical damage (e.g., local thermal adsorption and/or heating). Further, circulation of metal fluoride dust in the MO can also lead to reduced discharge voltage from the electrodes and poor laser performance.

In some embodiments, a metal fluoride trap (MFT) can be coupled to the chamber of the MO and to the chamber of the PA and/or the PRA to reduce contamination in the gas discharge medium.

Embodiments of light source apparatuses and systems disclosed herein may improve uniformity of the gas discharge intensity throughout the length of the electrodes, prevent uneven degradation of the electrodes, improve control of flow distribution through a window housing apparatus, provide an efficient purge without increasing clean gas backflow rates from a metal fluoride trap, reduce metal fluoride dusting on optical windows and increase the service lifetimes of both the metal fluoride trap and the master oscillator, the power amplifier, and/or the power ring amplifier to provide an excimer laser beam (e.g., DUV radiation), for example, to a DUV lithographic apparatus.

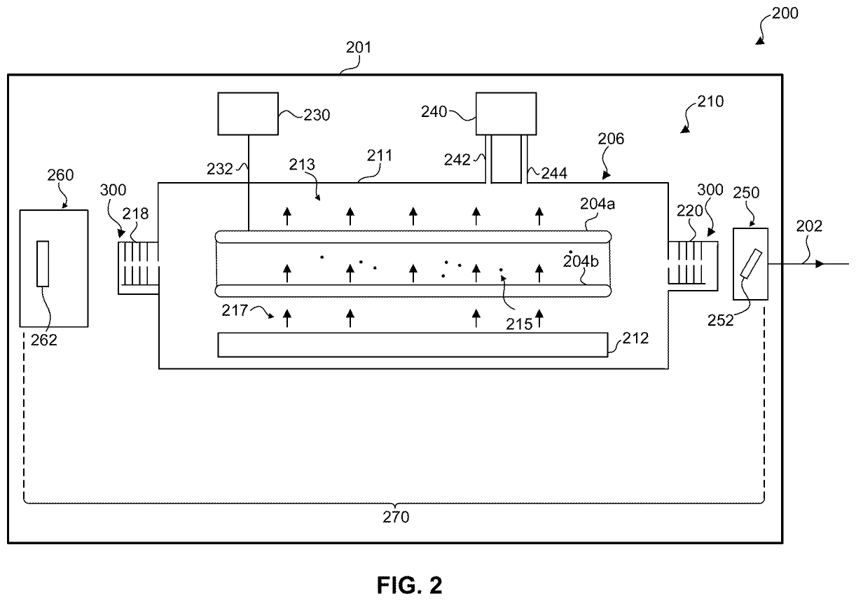

FIG. 2 illustrates light source apparatus 200, according to various exemplary embodiments. Light source apparatus 200 can provide a highly coherent and aligned laser beam (e.g., laser beam 202), for example, to a DUV lithographic apparatus (e.g., lithographic apparatus 100′). Although light source apparatus 200 is shown in FIG. 2 as a stand-alone apparatus and/or system, the embodiments of this disclosure can be used with other optical systems, such as, but not limited to, radiation source SO, lithographic apparatus 100, 100′, and/or other optical systems. In some embodiments, light source apparatus 200 can be radiation source SO in lithographic apparatus 100, 100′. For example, DUV radiation beam B can be laser beam 202. In some embodiments, light source apparatus 200 can be a MOPA or a MOPRA formed by gas discharge stage 210 (e.g., MO) and a second gas discharge stage (e.g., PA and/or PRA, similar to gas discharge stage 210) (not shown). As discussed above, for example, certain MOPAs and MOPRAs have been previously described in U.S. Pat. No. 7,643,528, issued Jan. 5, 2010, and U.S. Pat. No. 7,822,092, issued Oct. 26, 2010, which are hereby incorporated by reference herein in their entireties.

As shown in FIG. 2, light source apparatus 200 can include gas discharge stage 210, voltage control system 230, pressure control system 240. In some embodiments, all of the above listed components can be housed in a three-dimensional (3D) frame 201. For example, the 3D frame 201 can include a metal (e.g., aluminum, steel, etc.), a ceramic, and/or any other suitable rigid material.

Gas discharge stage 210 can be configured to output a highly coherent light beam (e.g., laser beam 202). Gas discharge stage 210 can include discharge chamber 206, first optical module 250 (e.g., optical coupler (OC), wavefront engineering box (WEB)), and second optical module 260 (e.g., linewidth narrowing module (LNM), beam reverser (BR)). In some embodiments, first optical module 250 can include first optical resonator element 252 and second optical module 260 can include second optical resonator element 262. Optical resonator 270 can be defined by first optical module 250 (e.g., via first optical resonator element 252) and second optical module 260 (e.g., via second optical resonator element 262). First optical resonator element 252 can be partially reflective (e.g., partial mirror) and second optical resonator element 262 can be reflective (e.g., mirror, grating, etc.) to form optical resonator 270. Optical resonator 270 can direct light generated by discharge chamber 206 to form coherent laser beam 202. In some embodiments, gas discharge stage 210 can output laser beam 202 to a PA stage (not shown) as part of a MOPA arrangement or a PRA stage (not shown) as part of a MOPRA arrangement. In some embodiments, gas discharge stage 210 can be a MO stage, for example, with an OC and a LNM. In some embodiments, gas discharge stage 210 can be a PA stage, for example, with a WEB and a BR. In some embodiments, gas discharge stage 210 can be a PRA stage, for example, with a WEB and a BR.

As shown in FIG. 2, discharge chamber 206 can include chamber body 211, first window housing apparatus 218, and second window housing apparatus 220. Chamber body 211 can be configured to hold gas discharge medium 213 within first and second window housing apparatuses 218, 220. As above, gas discharge medium 213 may represent a gas or gas medium prior to the gas having been broken down or excited and/or the plasma or discharge plasma formed when gas is broken down or excited and the arrows indicate gas flow of gas discharge medium 213. The plasma or discharge plasma formed is formed between the electrodes 204a, 204b in plasma region 215 when gas is broken down and/or excited. Chamber body 211 can include electrodes 204a, 204b (collectively referred to as electrodes 204), blower 212, gas discharge medium 213, first window housing apparatus 218, and second window housing apparatus 220. In some embodiments, the electrode 204a may be a cathode and the electrode 204b may be an anode, as should be understood by those of ordinary skill in the arts.

Discharge chamber 206 can be optically coupled to the optical resonator 270 defined by first optical module 250 and second optical module 260. Discharge chamber 206 can be configured to output amplified spontaneous emission (ASE) and/or laser beam 202 by breaking down the gas discharge medium 213 between electrodes 204 in chamber body 211 to convert a gas medium into a plasma discharge. Gas discharge medium 213 can be circulated between electrodes 204 in chamber body 211 by blower 212. In some embodiments, blower 212 can be a tangential blower that causes a gas flow 217.

Gas discharge medium 213 can be configured to output ASE and/or laser beam 202 (e.g., 193 nm). In some embodiments, gas discharge medium 213 can include a gas for excimer lasing (e.g., Ar₂, Kr₂, F₂, Xe₂, ArF, KrCl, KrF, XeBr, XeCl, XeF, etc.). For example, gas discharge medium 213 can form ArF upon excitation (e.g., applied voltage) from surrounding electrodes 204 in chamber body 211, and output ASE and/or laser beam 202 (e.g., 193 nm) through first and second window housing apparatuses 218, 220. In some embodiments, gas discharge medium 213 can include halogen gasses and noble gasses to form an excimer and/or an exciplex. For example, gas discharge medium 213 can include F₂, Ar, Kr, and/or Xe, forming ArF, KrF and/or XeF under discharge plasma.

In some embodiments, first optical module 250 can be configured to partially reflect a light beam and form part of optical resonator 270. For example, first optical modules (e.g., OCs, WEBs) have been previously described in U.S. Pat. No. 7,885,309, issued Feb. 8, 2011, and U.S. Pat. No. 7,643,528, issued Jan. 5, 2010, which are hereby incorporated by reference herein in their entireties. As shown in FIG. 2, first optical module 250 can include first optical resonator element 252 to direct light (e.g., ASE and/or laser beam 202) from discharge chamber 206 back into discharge chamber 206 and/or output laser beam 202. In some embodiments, first optical resonator element 252 can be adjusted (e.g., tilt).

In some embodiments, second optical module 260 can be configured to provide spectral line narrowing to a light beam and form part of optical resonator 270. As shown in FIG. 2, second optical module 260 can include second optical resonator element 262 to direct light (e.g., ASE and/or laser beam 202) from discharge chamber 206 back into discharge chamber 206 toward first optical module 250. In some embodiments, second optical resonator element 262 can be adjusted (e.g., tilt, angular).

Voltage control system 230 can be configured to apply high voltage electrical pulses across electrodes 204 in chamber body 211 to discharge and excite gas medium 213 to output ASE and/or laser beam 202 (e.g., 193 nm). Voltage control system 230 can include voltage supply line 232. In some embodiments, voltage control system 230 can include a high voltage power supply (not shown), a voltage compression amplifier (not shown), a pulse energy monitor (not shown), and/or a controller (not shown) for providing high voltage electrical pulses across electrodes 204.

Pressure control system 240 can be configured to control a fluorine concentration in chamber body 211 and provide gas discharge medium 213 to chamber body 211. Pressure control system 240 can include gas discharge line 242 and vacuum line 244. Gas discharge line 242 can be configured to provide one or more gas components (e.g., Ar, Kr, F₂, Xe, etc.) of gas discharge medium 213 to chamber body 211. Vacuum line 244 can be configured to provide a negative pressure (e.g., draw out) a portion of gas discharge medium 213 in chamber body 211, for example, during injection of one or more gas components to gas discharge medium 213 through gas discharge line 242. In some embodiments, gas discharge line 242 and vacuum line 244 are combined as one gas line. In some embodiments, pressure control system 240 can include one or more gas sources (not shown), one or more pressure regulators (not shown), a vacuum pump (not shown), a fluorine (F₂) trap, and/or a controller (not shown) for controlling a fluorine concentration in chamber body 211 and refilling gas discharge medium 213 in chamber body 211.

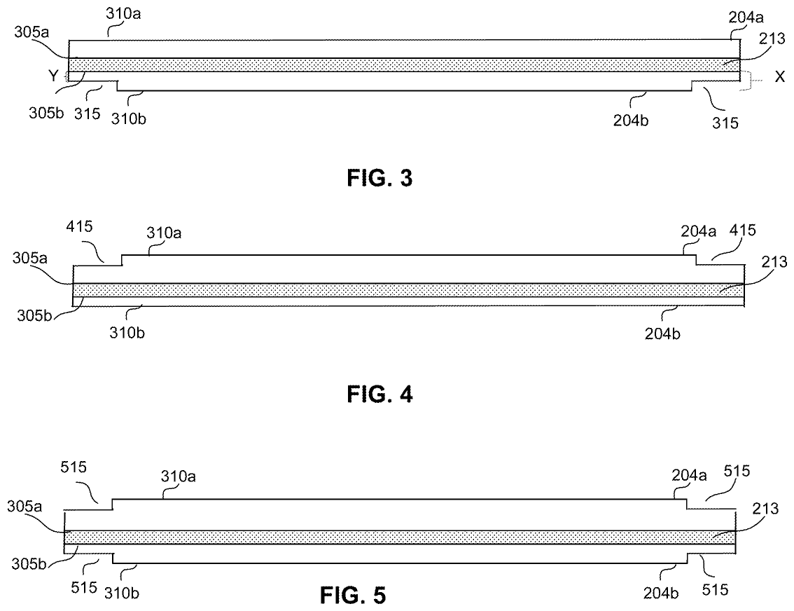

FIGS. 3-13 each illustrate a pair of electrodes in accordance with aspects of the present disclosure. Namely, FIGS. 3-13 illustrate a side-view of electrodes and a gas discharge medium 213 between the electrodes 204a and 204b. For example, as illustrated in FIGS. 3-6, each of the electrodes 204 (i.e. electrodes 204a and 204b) may include first surfaces 305a, 305b (collectively referred to as first surfaces 305), respectively, with the first surfaces 305 facing inward toward the gas discharge medium 213 which is a plasma when excited by the electrodes 204a and 204b. Additionally, each of the electrodes may include second surfaces 310a, 310b (collectively referred to as second surfaces 310), respectively, with the second surfaces 310 facing away from the gas discharge medium 213.

In some embodiments, one or more of the electrodes 204 may include recessed portions at each end of the electrode 204. The electrodes with the recessed portions may be referred to as undercut electrodes. For example, as shown in FIG. 3, the electrode 204b may include recessed portions 315 at each end of the electrode 204b. In some embodiments, the electrode 204b may include a recessed portion 315 only at one end of the electrode 204b. As above, in some embodiments, electrode 204a may be the cathode and electrode 204b the anode, but other arrangements are used in other embodiments. In some embodiments, the electrode 204b may have a bulk thickness X and a planar first surface inwardly facing the discharge plasma, and the recessed portions 315 comprise an undercut portion such that the ends of the electrode 204b have a thickness Y that is less than the bulk thickness X.

In another example shown in FIG. 4, the electrode 204a may include recessed portions 415 at each end of the electrode 204a.

In another example shown in FIG. 5, both of the electrodes 204 may include recessed portions 515 at each end of the electrodes 204. In some embodiments, one or both of the electrodes 204 may include a recessed portion 515 at only one end of the electrodes 204.

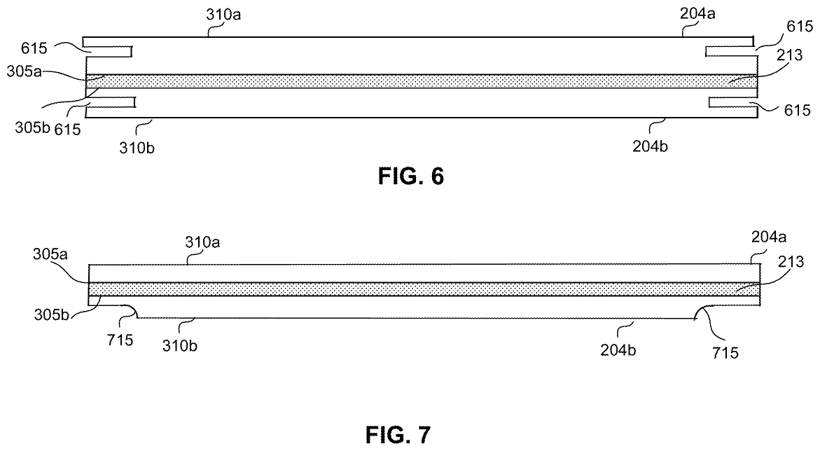

In another example shown in FIG. 6, the electrodes 204 may include recessed portions 615 at each end of the electrodes 204, with the recessed portions being formed between the first surface 305 and second surface 310 of each electrode 204. Although the example shown in FIG. 6 illustrates both electrodes as having the recessed portions 615, it should be understood by those of ordinary skill in the art that either or both electrodes 204 may have the recessed portions 615.

While the examples shown in FIGS. 3-6 illustrate the electrodes 204 as having rectangular, or squared, recessed portions, it should be understood by those of ordinary skill in the arts that these are merely used for illustrative purposes, and that other shaped recessed portions are further contemplated in accordance with aspects of the present disclosure. For example, as illustrated in FIG. 7, the recessed portions 715 of the electrode 204b may have a rounded edge. It should be understood by those of ordinary skill in the arts that the electrode 204a may likewise have a rounded as shown in FIG. 7.

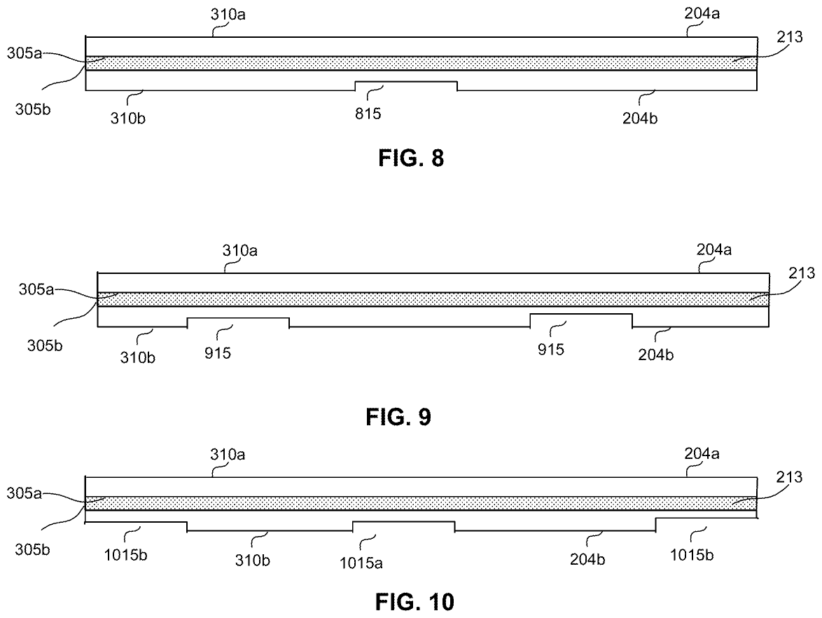

In one example shown in FIG. 8, the electrode 204b may include recessed portion 815 formed within the second surface 310b. In some embodiments, the recessed portion 815 may be centrally disposed along the length of the electrode 204b, i.e., the recessed portion 815 may be located along a centerline of the electrode 204b. In some embodiments, the recessed portion 815 may be locally undercut to even out the local erosion rate to match the rest of electrode 204b. Although FIG. 8 shows electrode 204b as having the recessed portion 815, it should be understood by those of ordinary skill in the art that the electrode 204a may likewise have the recessed portion 815 formed in the second surface 310a in accordance with aspects of the present disclosure. That is, in some embodiments, either or both electrodes 204a, 204b may include the recessed portion 815.

In one example shown in FIG. 9, the electrode 204b may include a plurality of recessed portions 915 formed within the second surface 310b. In some embodiments, the plurality of recessed portions 915 may be offset from the centerline of the electrode 204b. In some embodiments, the plurality of recessed portions 915 may be locally undercut to even out the local erosion rate to match the rest of electrode 204b. Although FIG. 9 shows electrode 204b as having the plurality of recessed portions 915, it should be understood by those of ordinary skill in the art that the electrode 204a may likewise have the plurality of recessed portions 915 in accordance with aspects of the present disclosure. That is, in some embodiments, either or both electrodes 204a, 204b may include the plurality of recessed portions 915.

In one example shown in FIG. 10, the electrode 204b may include a combination of a recessed portion 1015a formed within the second surface 310b and recessed portions 1015b at either, or both, ends of the electrode 204b. In some embodiments, the recessed portion 1015a may be formed along a centerline of the electrode 204b or the recessed portion 1015a may be offset from the centerline. In some embodiments, the recessed portion 1015a may be locally undercut to even out the local erosion rate to match the rest of electrode 204b. Although FIG. 10 shows electrode 204b as having the recessed portion 1015a and recessed portions 1015b, it should be understood by those of ordinary skill in the art that the electrode 204a may likewise have the recessed portion 1015a and recessed portions 1015b in accordance with aspects of the present disclosure. That is, in some embodiments, either or both electrodes 204a, 204b may include the recessed portion 1015a and recessed portions 1015b.

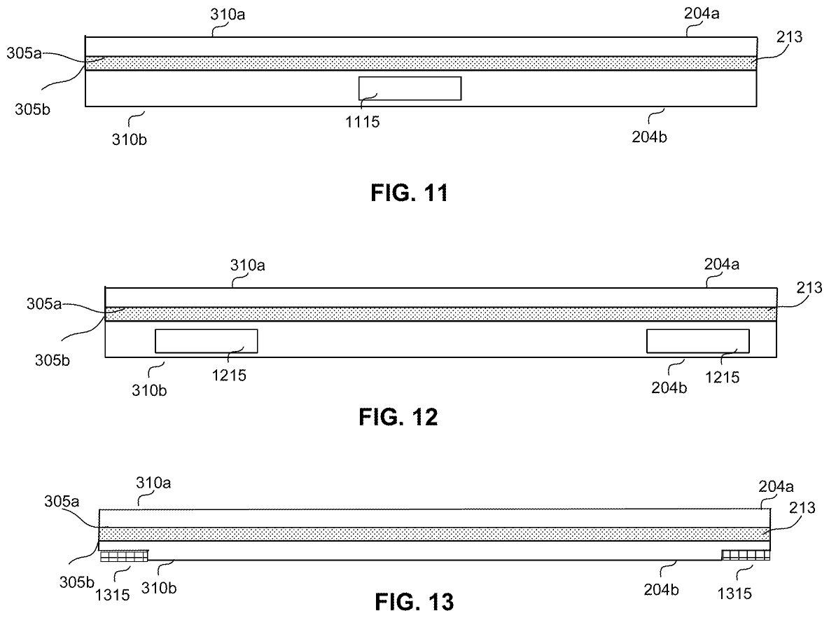

In one example shown in FIG. 11, the electrode 204b may include a hollowed-out portion 1115 formed within a body of the electrode 204b. In some embodiments, the hollowed-out portion 1115 may be formed along a centerline of the electrode 204b. In some embodiments, the hollowed-out portion 1115 may be locally undercut to even out the local erosion rate to match the rest of electrode 204b. Although FIG. 11 shows electrode 204b as having the hollowed-out portion 1115, it should be understood by those of ordinary skill in the art that the electrode 204a may likewise have the hollowed-out portion 1115 in accordance with aspects of the present disclosure. That is, in some embodiments, either or both electrodes 204a, 204b may include the hollowed-out portion 1115.

In one example shown in FIG. 12, the electrode 204b may include a plurality of hollowed-out portions 1215 formed within a body of the electrode 204b. In some embodiments, the plurality of hollowed-out portions 1215 may be offset from a centerline of the electrode 204b. In some embodiments, the plurality of hollowed-out portions 1215 may be locally undercut to even out the local erosion rate to match the rest of electrode 204b. Although FIG. 12 shows electrode 204b as having the plurality of hollowed-out portions 1215, it should be understood by those of ordinary skill in the art that the electrode 204a may likewise have the plurality of hollowed-out portions 1215 in accordance with aspects of the present disclosure. That is, in some embodiments, either or both electrodes 204a, 204b may include the plurality of hollowed-out portions 1215.

In some embodiments, the recessed portions and/or hollowed-out portions of the electrodes 204 in the examples shown in FIGS. 3-12 may be filled with a non-conductive material. For example, as shown in FIG. 13, the undercut portions of the electrode 204b may be filled with a non-conductive material 1315. In some embodiments, the non-conductive material 1315 may be, for example, a ceramic, plastic, polymers, or the like. It should be understood by those of ordinary skill in the art that these are merely examples of non-conductive materials, and that other non-conductive materials are contemplated in accordance with aspects of the present disclosure.

In some embodiments, the recessed portions and hollowed-out portions described herein may be combined with one another in any combination and at different positions of each to achieve optimally evened electrode erosion.

In some embodiments, a depth and height of the recessed portions of the electrodes 204 may be determined based on reducing the local discharge plasma intensity in the vicinity of the electrodes 204.

In some embodiments, the depth of the recessed portions may range from about 0.1 to about 10 cm and the height of the recessed portions may range from about 0.05 to about 5 cm. It should be understood by those of ordinary skill in the art that that these are merely example dimensions of the depth and height of the recessed portions of the electrodes 204 and that other dimensions are further contemplated in accordance with aspects of the present disclosure. For example, for different electrode material of the electrode or a different thickness of the electrode may require different dimensions of the recesses.

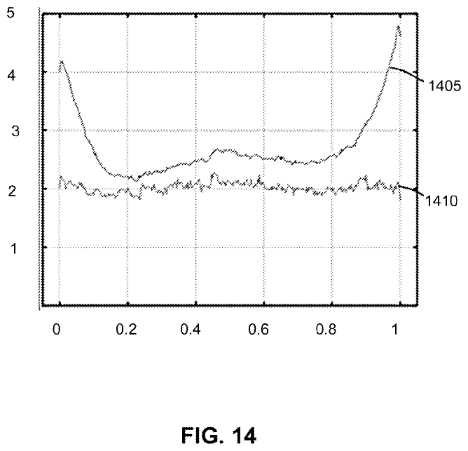

FIG. 14 is a graph that graphically illustrates an erosion performance of an undercut electrode of the present disclosure compared to the erosion performance of a conventional electrode. The performance graphs illustrate the erosion rate defined as the electrode height change per certain number of laser pulses versus location on the electrode in an arbitrary unit. FIG. 14 shows a first erosion rate of a conventional electrode 1405 and an erosion rate of the embodiment shown in FIG. 3. FIG. 14 shows that, for example, the first erosion rate 1405 suffers from increased erosion at each end of the conventional electrode, and at the center of the conventional electrode, in comparison to an interior portion of the electrode. In some embodiments, as shown in the first erosion rate 1405, each end of the conventional electrode exhibits an erosion rate that is 2-2.5 times greater than the erosion rate at the center portion of the same electrode.

In some embodiments, the second erosion rate 1410 of the undercut electrode shown in FIG. 3 illustrates a more uniform erosion rate across the full length of the electrode. In some embodiments, each end of the conventional electrode erodes at a rate 1405 that is 2-2.5 times greater than the second erosion rate 1410 at the edge portions of the electrode shown in FIG. 3. Each end of the undercut electrode may have a comparable erosion rate to the center portion of the undercut electrode. In some aspects, due the even erosion of the electrodes, a lifespan of the electrodes 204 may be increased. For example, the improved erosion rate of the ends of the electrodes and evened-out erosion profile of FIG. 14 may be a result of reduced discharge plasma intensity at the ends where the electrode is undercut compared to a conventional design or the reduced discharge plasma intensity at the ends may be due to hollowed-out portions at the ends of the electrodes or due to an undercut or hollowed-out portion filled with a non-conductive material undercut such as shown in FIGS. 3-13.

In some embodiments, such as the embodiments shown in FIGS. 8, 9, 11, and 12, the reduced erosion rate at the location of the undercut portion due to reduce discharge plasma intensity at that location, will also result in a similar evened-out erosion profile, such as that shown in the second erosion rate 1410.

Although specific reference may have been made above to the use of embodiments in the context of optical lithography, it will be appreciated that embodiments may be used in other applications, for example imprint lithography, and where the context allows, is not limited to optical lithography.

It is to be understood that the phraseology or terminology herein is for the purpose of description and not of limitation, such that the terminology or phraseology of the present specification is to be interpreted by those skilled in relevant art(s) in light of the teachings herein.

The term “substrate” as used herein describes a material onto which material layers are added. In some embodiments, the substrate itself may be patterned and materials added on top of it may also be patterned, or may remain without patterning.

The following examples are illustrative, but not limiting, of the embodiments of this disclosure. Other suitable modifications and adaptations of the variety of conditions and parameters normally encountered in the field, and which would be apparent to those skilled in the relevant art(s), are within the spirit and scope of the disclosure.

While specific embodiments have been described above, it will be appreciated that the embodiments may be practiced otherwise than as described. The description is not intended to limit the scope of the claims.

It is to be appreciated that the Detailed Description section, and not the Summary and Abstract sections, is intended to be used to interpret the claims. The Summary and Abstract sections may set forth one or more but not all exemplary embodiments as contemplated by the inventor(s), and thus, are not intended to limit the embodiments and the appended claims in any way.

The embodiments have been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed.

The foregoing description of the specific embodiments will so fully reveal the general nature of the embodiments that others can, by applying knowledge within the skill of the art, readily modify and/or adapt for various applications such specific embodiments, without undue experimentation, without departing from the general concept of the embodiments. Therefore, such adaptations and modifications are intended to be within the meaning and range of equivalents of the disclosed embodiments, based on the teaching and guidance presented herein.

The breadth and scope of the embodiments should not be limited by any of the above-described exemplary embodiments, but should be defined only in accordance with the following claims and their equivalents.

Other aspects of the invention are set out in the following numbered clauses.

1. A light source apparatus comprising:
a chamber configured to hold a gas discharge medium; and
a pair of opposed electrodes configured to excite the gas discharge medium to produce a plasma that produces an output light beam,
wherein at least one electrode of the pair of opposing electrodes comprises recessed portions formed at each end of the at least one electrode.
2. The light source apparatus of clause 1, wherein each electrode of the pair of electrodes comprises:
a first surface inwardly facing the gas discharge medium; and
a second surface opposite the first surface, wherein the recessed portions of the at least one electrode are formed within the second surface at each end of the second surface.
3. The light source apparatus as in clause 1, wherein the at least one electrode includes a bulk thickness and a planar first surface inwardly facing the gas discharge medium, and wherein the recessed portions each comprise an undercut portion wherein the ends of the at least one electrode have a thickness less than the bulk thickness.
4. The light source apparatus of clause 1, wherein the at least one electrode of the pair of electrodes comprises an anode.
5. The light source apparatus of clause 1, wherein the at least one electrode of the pair of electrodes comprises a cathode.
6. The light source apparatus of clause 1, wherein each electrode of the pair of electrodes comprises the recessed portions formed at each end.
7. The light source apparatus of clause 1, wherein each electrode of the pair of electrodes comprises:
a first surface inwardly facing the gas discharge medium; and
a second surface opposite the first surface, and wherein the recessed portions of the at least one electrode are hollowed-out portions formed between the first and second surfaces.
8. The light source apparatus of clause 1, wherein the gas discharge medium comprises halogen gasses and noble gasses to form an excimer and/or an exciplex.
9. The light source apparatus of clause 1, wherein the gas discharge medium comprises F₂, ArF, KrF, and/or XeF.
10. The light source apparatus of clause 1, further comprising:
a set of optical elements configured to form an optical resonator around the chamber.
11. An undercut electrode comprising:
a first surface inwardly facing a gas discharge medium;
a second surface opposite the first surface; and recessed portions formed at each end of the undercut electrode.
12. The undercut electrode of clause 11, wherein the undercut electrode includes a bulk thickness, and wherein the recessed portions each comprise an undercut portion within the second surface wherein the ends of the undercut electrode have a thickness less than the bulk thickness.
13. The undercut electrode of clause 11, wherein the recessed portions are hollowed-out portions formed between the first and second surfaces.
14. The undercut electrode of clause 13, wherein the hollowed-out portions are filled with a non-conductive material.
15. The undercut electrode of clause 11, wherein the recessed portions comprise rectangular shaped recesses.
16. The undercut electrode of clause 11, wherein the recessed portions comprise curved recesses.
17. The undercut electrode of clause 11, wherein the undercut electrode comprises an anode.
18. The undercut electrode of clause 11, wherein the undercut electrode comprises a cathode.
19. A pair of opposing electrodes configured to excite a gas medium to form a plasma, each electrode of the pair of electrodes comprising:
a first surface inwardly facing the gas medium; and
a second surface opposite the first surface,
wherein at least one electrode of the pair of opposing electrodes comprises recessed portions formed at each end of the at least one electrode.
20. The pair of opposing electrodes of clause 19, wherein the at least one electrode includes a bulk thickness and the first surface comprises a planar surface inwardly facing the gas discharge medium, and wherein the recessed portions each comprise an undercut portion wherein the ends of the at least one electrode have a thickness less than the bulk thickness.
21. The pair of opposing electrodes of clause 19, wherein the recessed portions comprise rectangular shaped recesses.
22. The pair of opposing electrodes of clause 19, wherein the recessed portions comprise curved recesses.
23. The pair of opposing electrodes of clause 19, wherein each electrode of the pair of electrodes comprises recessed portions formed at each end.
24. A light source apparatus comprising:
a chamber configured to hold a gas discharge medium; and
a pair of opposed electrodes configured to excite the gas discharge medium to produce a plasma that produces an output light beam,
wherein at least one electrode of the pair of opposing electrodes comprises at least one of a recessed portion or a hollowed-out portion.
25. The light source apparatus of clause 24, wherein each electrode of the pair of electrodes comprises:
a first surface inwardly facing the gas discharge medium; and
a second surface opposite the first surface, wherein the at least one electrode comprises the recessed portion, the recessed portion being formed within the second surface.
26. The light source apparatus of clause 24, wherein the recessed portion comprises a plurality of recessed portions.
27. The light source apparatus of clause 26, wherein the plurality of recessed portions are located at each end of the at least one electrode.
28. The light source apparatus of clause 24, wherein each electrode of the pair of electrodes comprises:
a first surface inwardly facing the gas discharge medium; and
a second surface opposite the first surface, wherein the at least one electrode comprises the hollowed-out portion, the hollowed-out portion being formed between the first and second surfaces.
29. The light source apparatus of clause 28, wherein the hollowed-out portion comprises a plurality of hollowed-out portions.
30. The light source of clause 29, wherein each of the plurality of hollowed-out portions is filled with a non-conductive material.
31. The light source apparatus of clause 24, wherein the recessed portion or hollowed-out portion is located along a centerline of the at least one electrode.
32. The light source apparatus of clause 24, wherein the recessed portion or hollowed-out portion is located at an end of the at least one electrode.
33. The light source apparatus of clause 24, wherein the recessed portion or hollowed-out portion is offset from a centerline of the at least one electrode.
34. The light source apparatus of clause 24, wherein the least one electrode comprises the recessed portion and the hollowed-out portion.
35. The light source apparatus of clause 24, wherein the at least one of the recessed portion or the hollowed-out are filled with a non-conductive material.

The breadth and scope of the embodiments should not be limited by any of the above-described exemplary embodiments, but should be defined only in accordance with the following claims and their equivalents.

1. A light source apparatus comprising:
a chamber configured to hold a gas discharge medium; and
a pair of opposed electrodes configured to excite the gas discharge medium to produce a plasma that produces an output light beam,
wherein at least one electrode of the pair of opposing electrodes comprises recessed portions formed at each end of the at least one electrode.

2. The light source apparatus of claim 1, wherein each electrode of the pair of electrodes comprises:
a first surface inwardly facing the gas discharge medium; and
a second surface opposite the first surface, wherein the recessed portions of the at least one electrode are formed within the second surface at each end of the second surface.

3. The light source apparatus as in claim 1, wherein the at least one electrode includes a bulk thickness and a planar first surface inwardly facing the gas discharge medium, and wherein the recessed portions each comprise an undercut portion wherein the ends of the at least one electrode have a thickness less than the bulk thickness.

4. (canceled)

5. (canceled)

6. The light source apparatus of claim 1, wherein each electrode of the pair of electrodes comprises the recessed portions formed at each end.

7. The light source apparatus of claim 1, wherein each electrode of the pair of electrodes comprises:
a first surface inwardly facing the gas discharge medium; and
a second surface opposite the first surface, and wherein the recessed portions of the at least one electrode are hollowed-out portions formed between the first and second surfaces.

8. The light source apparatus of claim 1, wherein the gas discharge medium comprises halogen gasses and noble gasses to form at least one of an excimer and an exciplex.

9. (canceled)

10. (canceled)

11. An undercut electrode comprising:
a first surface inwardly facing a gas discharge medium;
a second surface opposite the first surface; and
recessed portions formed at each end of the undercut electrode.

12. The undercut electrode of claim 11, wherein the undercut electrode includes a bulk thickness, and wherein the recessed portions each comprise an undercut portion within the second surface wherein the ends of the undercut electrode have a thickness less than the bulk thickness.

13. The undercut electrode of claim 11, wherein the recessed portions are hollowed-out portions formed between the first and second surfaces.

14. The undercut electrode of claim 13, wherein the hollowed-out portions are filled with a non-conductive material.

15. (canceled)

16. (canceled)

17. (canceled)

18. (canceled)

19. A pair of opposing electrodes configured to excite a gas medium to form a plasma, each electrode of the pair of electrodes comprising:
a first surface inwardly facing the gas medium; and
a second surface opposite the first surface,
wherein at least one electrode of the pair of opposing electrodes comprises recessed portions formed at each end of the at least one electrode.

20. The pair of opposing electrodes of claim 19, wherein the at least one electrode includes a bulk thickness and the first surface comprises a planar surface inwardly facing the gas discharge medium, and wherein the recessed portions each comprise an undercut portion wherein the ends of the at least one electrode have a thickness less than the bulk thickness.

21. (canceled)

22. (canceled)

23. (canceled)

24. A light source apparatus comprising:
a chamber configured to hold a gas discharge medium; and
a pair of opposed electrodes configured to excite the gas discharge medium to produce a plasma that produces an output light beam,
wherein at least one electrode of the pair of opposing electrodes comprises at least one of at least one recessed portion or at least one hollowed-out portion.

25. The light source apparatus of claim 24, wherein each electrode of the pair of electrodes comprises:
a first surface inwardly facing the gas discharge medium; and
a second surface opposite the first surface,
wherein the at least one electrode comprises the at least one recessed portion, the at least one recessed portion being formed within the second surface.

26. (canceled)

27. (canceled)

28. The light source apparatus of claim 24, wherein each electrode of the pair of electrodes comprises:
a first surface inwardly facing the gas discharge medium; and
a second surface opposite the first surface,
wherein the at least one electrode comprises the at least one hollowed-out portion, the at least one hollowed-out portion being formed between the first and second surfaces.

29. The light source apparatus of claim 28, wherein the at least one hollowed-out portion comprises a plurality of hollowed-out portions.

30. The light source of claim 29, wherein each of the plurality of hollowed-out portions is filled with a non-conductive material.

31. (canceled)

32. (canceled)

33. The light source apparatus of claim 24, wherein the at least one recessed portion or at least one hollowed-out portion is offset from a centerline of the at least one electrode.

34. The light source apparatus of claim 24, wherein the least one electrode comprises the at least one recessed portion and the at least one hollowed-out portion.

35. The light source apparatus of claim 24, wherein the at least one of the at least one recessed portion or the at least one hollowed-out are filled with a non-conductive material.
